(19) United States
(12) Patent Application Publication
(10) Pub. No.: US 2012/0315724 A1
(43) Pub. Date: Dec. 13, 2012

(54) METHOD AND APPARATUS FOR DEPOSITION OF SELENIUM THIN-FILM AND PLASMA HEAD THEREOF

(75) Inventors: Chi-Hung Liu, Taichung County (TW); Kuo-Hui Yang, Kaohsiung City (TW); Chen-Der Tsai, Hsinchu County (TW); Ying-Fang Chang, Hsinchu City (TW); Ta-Hsin Chou, Hsinchu City (TW)

(73) Assignee: INDUSTRIAL TECHNOLOGY RESEARCH INSTITUTE, Hsinchu (TW)

(21) Appl. No.: 13/230,788

(22) Filed: Sep. 12, 2011

(30) Foreign Application Priority Data
Jun. 8, 2011 (TW) TW100119931

(51) Int. Cl. H01L 21/06; C23C 16/50

(52) U.S. Cl. 438/102; 118/723 R; 257/E21.068

(57) ABSTRACT

A method for deposition of a selenium thin-film includes the following steps. First, a plasma head is provided. Then, a substrate is supported in an atmospheric pressure. Next, a solid-state selenium source is dissociated by the plasma head to deposit the selenium thin-film on the substrate. The plasma head includes a chamber, a housing and the solid-state selenium source. Plasma is produced in the chamber. The chamber is surrounded by the housing. The solid-state selenium source is supported by the housing.

### CROSS REFERENCE TO RELATED APPLICATIONS

This application claims priority of Taiwan Patent Application No. 100119931, filed on Jun. 8, 2011, the entirety of which is incorporated by reference herein.

### BACKGROUND

1. Technical Field

The disclosure relates to a method for deposition of a selenium thin-film, and more particularly to a method and an apparatus for deposition of a selenium thin-film by dissociation of a solid-state selenium source via plasma.

2. Description of the Related Art

Along with developments in solar cells, thin-film solar cells have been prized because of many advantages including simple construction. Among various types of thin-film solar cells, many nations are increasing their investment in copper, indium, gallium and selenium (Cu(In₁₋ₓGaₓ)(Se)₂, i.e. “CIGS”) thin-film solar cells because of high energy conversion efficiency. However, CIGS thin-film solar cells are difficult to mass produce because of the thin-film quality of their absorber layers, such as composition ratio, grain size, and denseness. Regarding the thin-film quality, the selenization process is a critical one.

The sputtering method and the co-evaporation method are known as representative methods for producing the absorber layers.

The sputtering methods have been disclosed, for example, in U.S. Pub. No. 2009/0215224 and S. J. Ahn. et al., “Cu(In,Ga)(Se)₂ layers from selenization of spray deposited nanoparticles”, Current Applied Physics, (2008), 766. The sputtering process is performed between two chambers. Since the sputtering technique has been well developed, the absorber layer can utilize a binary target or tertiary target prior to selenium thin-film deposition, followed by annealing. Compared with the co-evaporation method, the sputtering method is suitable for large-area manufacturing of solar cells.

The co-evaporation method has been disclosed, for example, in U.S. Pub. No. 2008/0072962. A selenium source is used in the film-coating process of the co-evaporation method. To improve the thin-film quality of the absorber layer, an additional chamber for annealing to supply selenium is needed. Furthermore, compared with the sputtering method, the selenium source uses liquid selenium, rather than H₂Se gas. Moreover, higher energy conversion efficiency can be obtained by the co-evaporation method when producing CIGS thin-film solar cells

But, both the sputtering method and the co-evaporation method must be performed in a vacuum apparatus. Also, selenium is easily released during the high-temperature process so that the composition ratio of the absorber layer changes. Furthermore, the utilization efficiency of the selenium source is markedly low. For example, in the co-evaporation method, since the reactivity of selenium molecules is low, it is necessary to produce a film at a high temperature of above 500° C. Most of selenium, however, adheres to the inner wall or the similar structure of the deposition chamber, thus, making it impossible to reproduce the same process in the polluted chamber.

### SUMMARY

The disclosure provides a method and an apparatus for deposition of a selenium thin-film by dissociating a solid-state selenium source via plasma.

The disclosure provides a method, for deposition of a selenium thin-film, including the following steps. A plasma head is provided. Then, a substrate is supported in an atmospheric pressure. Subsequently, a solid-state selenium source is dissociated by the plasma head to deposit the selenium thin-film on the substrate.

The disclosure further provides an apparatus, for deposition of a selenium thin-film, including a support table and a plasma head. The support table supports a substrate. The plasma head holds a solid-state selenium source, and is disposed in a manner such that the plasma head and the support table move relative to each other. The solid-state selenium source is dissociated by the plasma head so that the selenium thin-film is deposited on the substrate.

The disclosure further provides a plasma head including a chamber, a housing, and a solid-state selenium source. The chamber generates plasma. The housing is connected to the chamber in a manner such that the chamber is surrounded by the housing. The solid-state selenium source is disposed in the housing.

A detailed description is given in the following embodiments with reference to the accompanying drawings.

### BRIEF DESCRIPTION OF THE DRAWINGS

The disclosure can be more fully understood by reading the subsequent detailed description and examples with reference to the accompanying drawings, wherein:

FIG. 1a shows a schematic top view of an apparatus for deposition of a selenium thin-film according to an embodiment of the disclosure;

FIG. 1b shows a schematic cross section viewed along an A-A line in FIG. 1a;

FIG. 1c shows a schematic perspective view of the apparatus, shown in FIG. 1a, partially cut along the A-A line;

FIG. 1d shows a schematic cross section viewed along a B-B line in FIG. 1a;

FIG. 1e shows a schematic perspective view of the apparatus, shown in FIG. 1a, partially cut along the B-B line;

FIG. 1f shows a schematic cross section viewed along a C-C line in FIG. 1a;

FIG. 1g shows a schematic perspective view of the apparatus, shown in FIG. 1a, partially cut along the C-C line;

FIG. 2a shows an enlarged view of a portion D1 in FIG. 1b;

FIG. 2b shows an enlarged view of a portion D2 in FIG. 1c;

FIG. 3 shows a schematic view of an apparatus for deposition of a selenium thin-film according to a variant embodiment of the disclosure;

FIG. 4a shows a schematic top view of an apparatus for deposition of a selenium thin-film according to another variant embodiment of the disclosure;

FIG. 4b shows a schematic side view of the apparatus shown in FIG. 4a; and

FIG. 4c shows another schematic top view of the apparatus shown in FIG. 4a, wherein a plasma head is located above a substrate.

### DETAILED DESCRIPTION

The following description is of the best-contemplated mode of carrying out the disclosure. The description is provided for illustrating the general principles of the disclosure and is not meant to be limiting. The scope of the disclosure is best determined by reference to the appended claims.

The disclosure provides a method and an apparatus, for deposition of a selenium thin-film by dissociating a solid-state selenium source via plasma, which is applied in supplying selenium or depositing the selenium thin-film on absorber layers of CIGS thin-film solar cells.

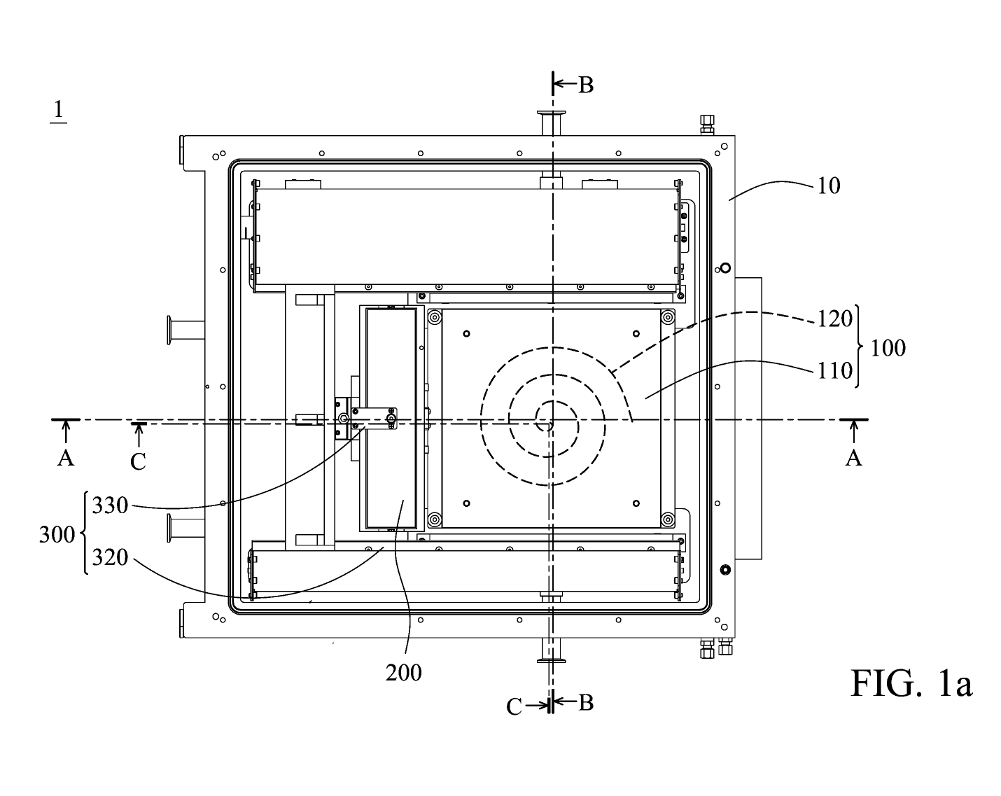

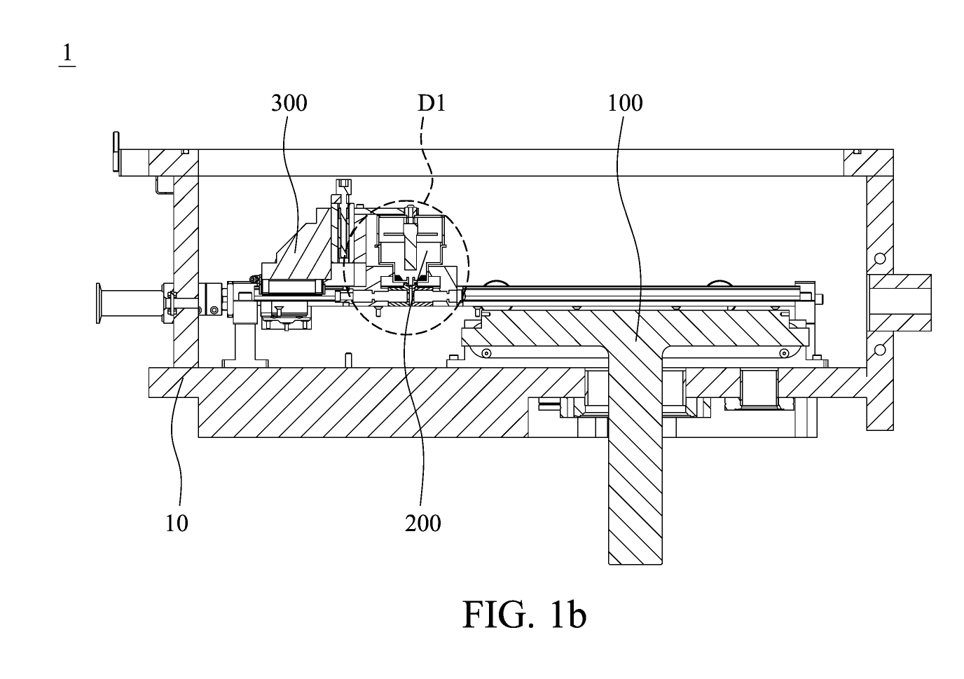

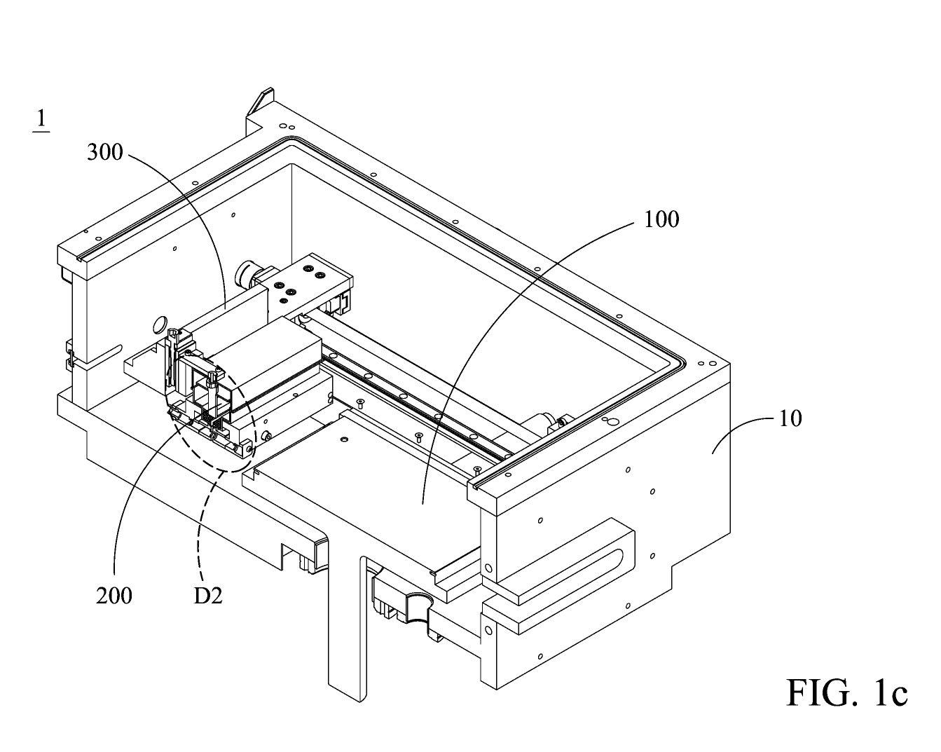

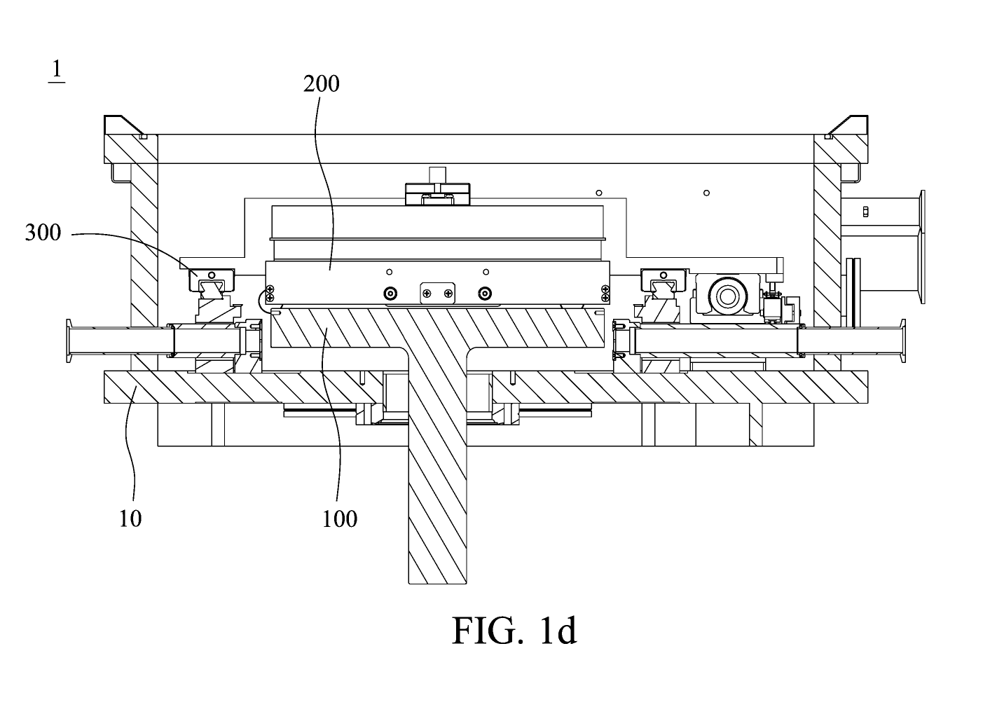

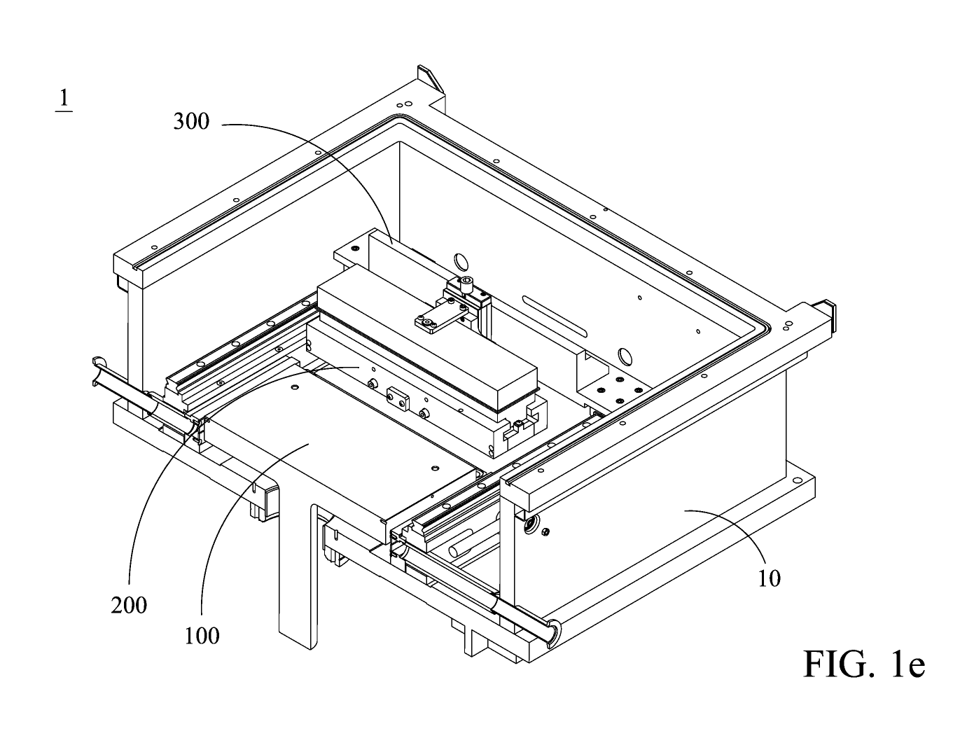

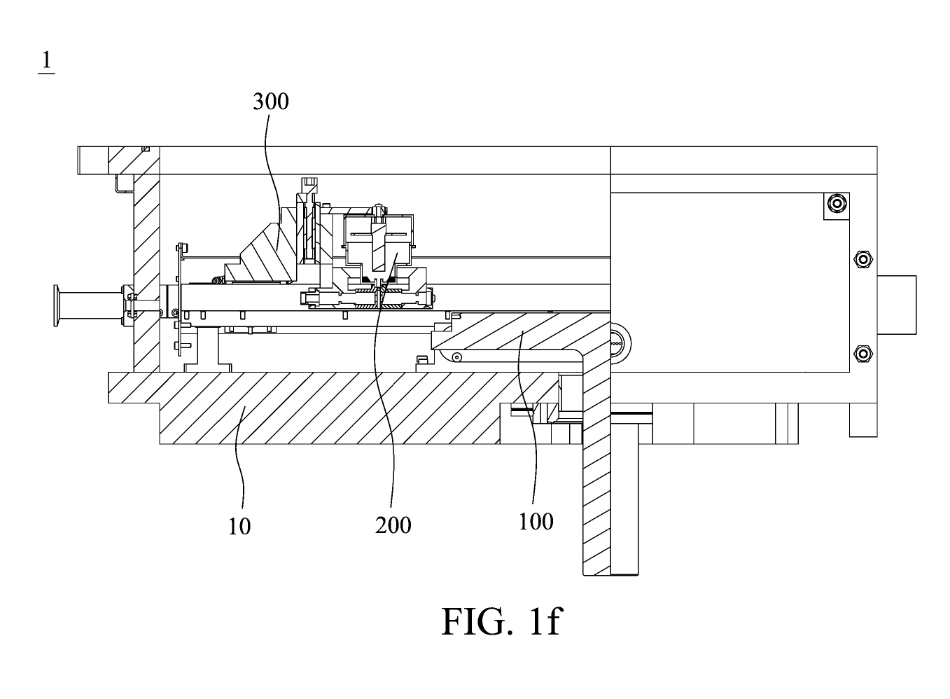

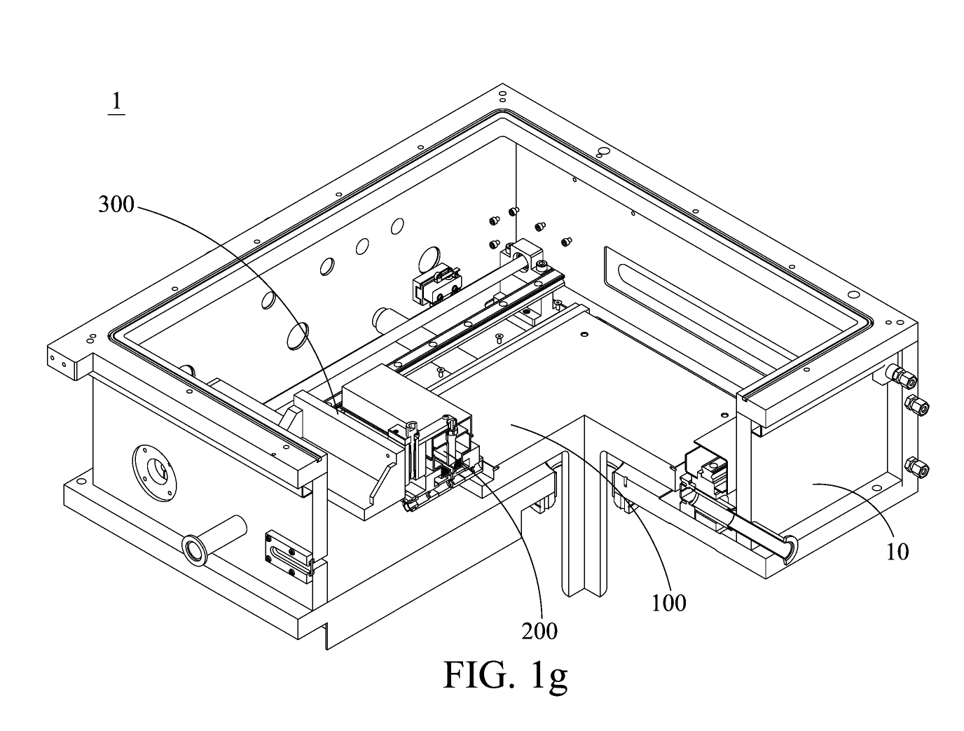

Referring to FIG. 1a, FIG. 1b, FIG. 1c, FIG. 1d, FIG. 1e, FIG. 1f and FIG. 1g, an apparatus 1 for deposition of a selenium thin-film according to an embodiment of the disclosure is described. In this embodiment, the apparatus 1 is performed in a pressure environment of 500 to 760 Torr.

In this embodiment, the apparatus 1 includes a main body 10, a support table 100, a plasma head 200 and a transmission mechanism 300. The main body 10 is used as a base and a frame of the apparatus 1, and supports the support table 100, the plasma head 200 and the transmission mechanism 300 therein.

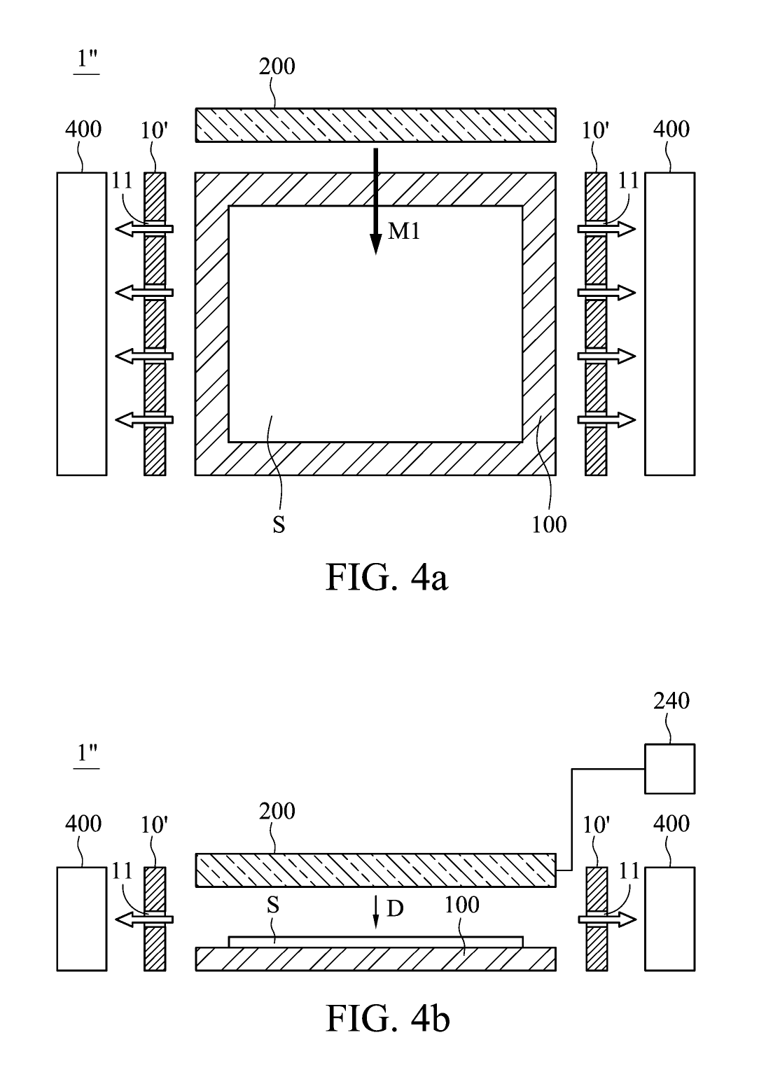

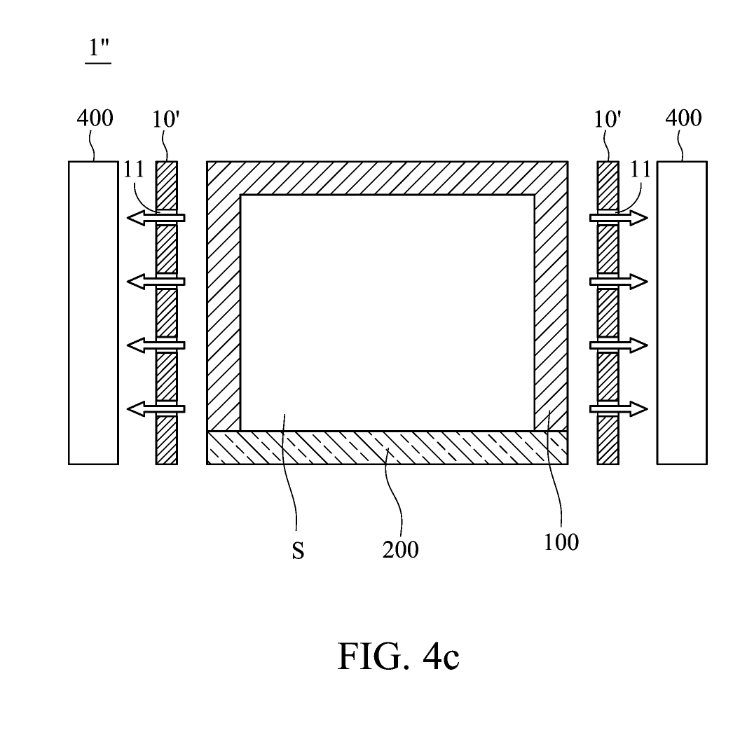

The support table 100 is disposed in the main body 10, and supports a substrate S shown in FIGS. 4a and 4b thereon. Generally, the substrate S, used in the process for manufacturing thin-film solar cells, is a glass substrate, such as a sodium alkaline glass substrate. For developing flexible solar cells, however, the substrate may be a non sodium alkaline glass substrate, such as a metal sheet (for example, stainless steel or Ti foil) or a polymer substrate (for example, polyimide).

As shown in FIG. 1a, the support table 100 includes a platen 110 and a heating device 120. The platen 110 supports the substrate S thereon. The heating device 120 is coil-shaped, and is embedded in the platen 110 to heat the substrate S while or after the selenium thin-film is being deposited. It is understood that the shape of the heating device 120 is not limited to the coil as long as it can heat the substrate S on the platen 110. For example, the heating device may be a heating plate or a heating rod. Furthermore, although the heating device 120 is embedded in the platen 110 in this embodiment, it is not limited to this. For example, the heating device may be independent of the platen 110.

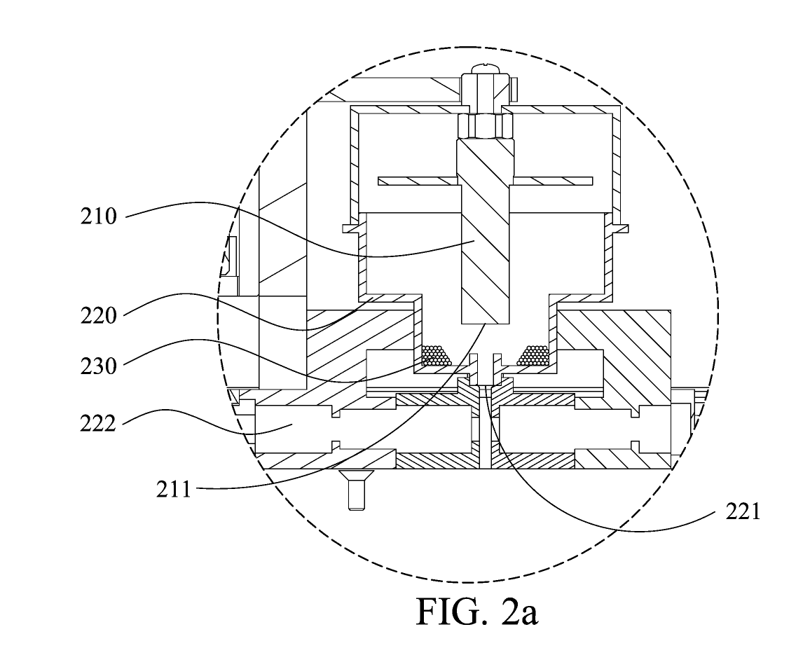

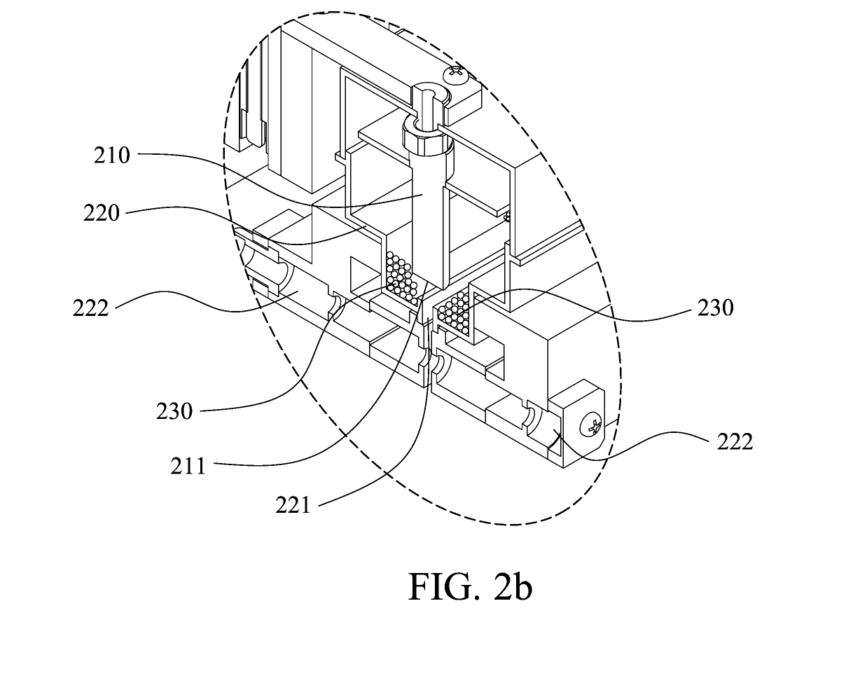

The plasma head 200 is disposed on the support table 100 in a manner such that the plasma head 200 and the support table 100 move relative to each other. As shown in FIGS. 2a and 2b, the plasma head 200 includes a chamber 210, a housing 220 and a solid-state selenium source 230. An inert gas is introduced into the chamber 210, and is energized by an energy source (not shown) to generate plasma. The energy source may be DC, AC, or RF. The inert gas may be Ar, N₂, or He. The chamber 210 includes a plasma exit 211.

The housing 220 holds the solid-state selenium source 230, and is connected to the chamber 210 in a manner such that the chamber 210 is surrounded by the housing 220. As shown in FIG. 2b, the housing 220 includes a slit-shaped injection exit 221 facing the plasma exit 211.

The solid-state selenium source 230 is located near the plasma exit 211, and is disposed in the housing 220. The solid-state selenium source 230 is dissociated by the plasma from the plasma exit 211 so that the selenium thin-film is deposited on the substrate S. Specifically, the solid-state selenium source 230 in the plasma head 200 is excited by electrons or ions of the plasma in the excitation state so that large molecules of the solid-state selenium source 230 are dissociated to small molecules and radicals with activity, thus increasing reactivity and utilization efficiency.

Moreover, as shown in FIGS. 2a and 2b, the solid-state selenium source 230 is not disposed in the chamber 210, thus preventing the reactant from adhering to electrodes in the chamber 210.

As the solid-state selenium source 230 in FIGS. 2a and 2b, a plurality of selenium tablets is disposed at an inner wall of the housing 220; however, the disclosure is not limited thereto. For example, a ring-shaped solid-state selenium may be disposed at the inner wall of the housing 220, or the solid-state selenium may be coated at the inner wall of the housing 220.

The distance between the injection exit 221 and the substrate S may be adjusted based on process conditions.

In this embodiment, since the plasma head is used for supplying selenium on the absorber layers of CIGS thin-film solar cells, the selenium source is disposed in the plasma head. It is understood that the material source to be dissociated is not limited. Based on the required process, a non-selenium source may be disposed in the plasma head. For example, a carbon source may be utilized for a surface modification process.

Corresponding to different process conditions, the structure of the plasma head may be properly adjusted. For example, when the substrate S is a non sodium alkaline glass substrate, the plasma head 200 further includes an inlet 222 located at a side of the housing 220 and communicating with a sodium fluoride source 240 as shown in FIG. 4b. Sodium fluoride from the sodium fluoride source 240 is introduced into the plasma head 200 via the inlet 222, and is dissociated by the plasma to increase the sodium component on the substrate S. Since sodium is supplied, the thin-film quality of the absorber layer is enhanced, thus increasing energy conversion efficiency. Furthermore, sodium may be supplied while or after the selenium thin-film is being deposited on the substrate. The sodium source for supplying sodium is not limited to the sodium fluoride source as long as sodium can be supplied. For example, the sodium source may a sodium selenate source.

Referring to FIGS. 1a-1g again, the transmission mechanism 300 is disposed on the main body 10, and is connected to the plasma head 200 to move the plasma head 200 relative to the support table 100. In this embodiment, the transmission mechanism 300 includes a conveyor 320, a joint 330 connected with the plasma head 200, and a motor (not shown). The conveyor 320 is driven by the motor so as to move the plasma head 200 reciprocally. Thus, large-area manufacturing can be attained. As shown in FIG. 1d, the conveyor 320 includes a guide rail; however, it is not limited to this as long as it can move the plasma head reciprocally. For example, the conveyer may include a belt or a gear.

In this embodiment, the plasma head is moved by the transmission mechanism; however, it is not limited to this. For example, the support table may be moveable so that plasma head and the substrate move relative to each other.

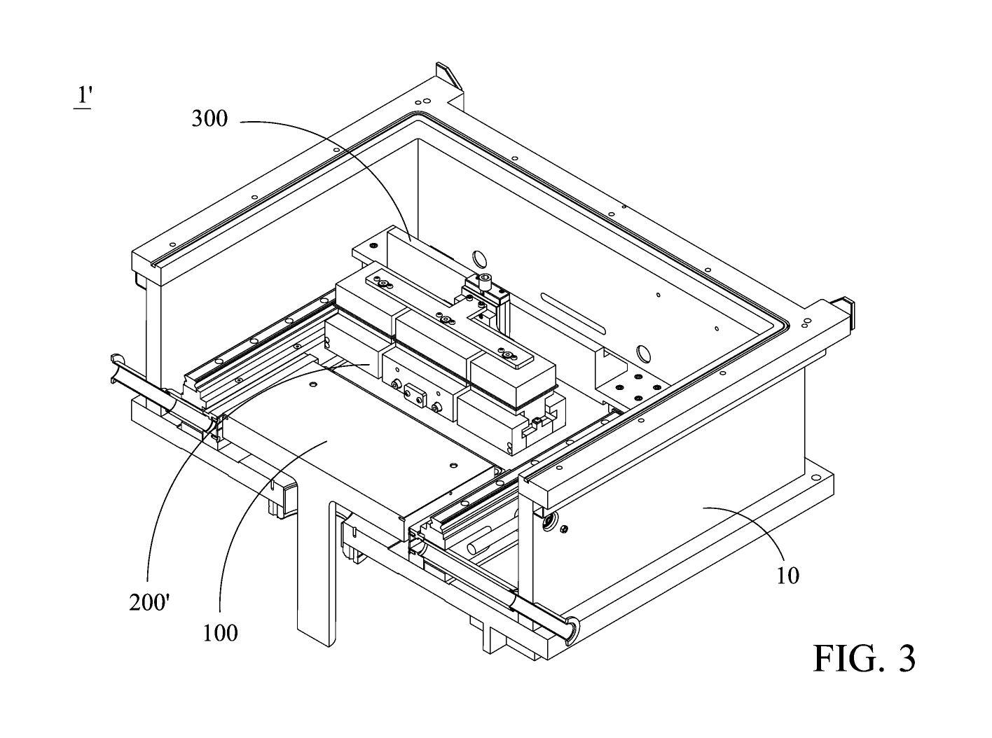

FIG. 3 shows a schematic view of an apparatus 1′ for deposition of a selenium thin-film according to a variant embodiment of the disclosure. The difference between the apparatus 1′ of this embodiment and the apparatus 1 is that the apparatus 1′ includes a plasma head module 200′. Specifically, the plasma head module 200′ includes three juxtaposed heads disposed on the support table 100, and is driven by the transmission mechanism 300 to attain large-area manufacturing. Since the plasma head module 200′ includes a plurality of heads, the injection exit of the housing of each head is not limited to be slit-shaped. For example, corresponding to the number of heads, the injection exit may be dot-shaped or line-shaped.

FIGS. 4a-4c show schematic views of an apparatus 1″ for deposition of a selenium thin-film according to another variant embodiment of the disclosure. The difference between the apparatus 1″ of this embodiment and the apparatus 1 is that the apparatus 1″ further includes an extraction device 400, disposed around the main body 10 and the support table 100, extracting the air from the opposite sides of the substrate S supported on the support table 100 to enhance uniformity of the flow field around the substrate S. Corresponding to the extraction device 400, the main body 100 includes a plurality of extraction holes 11. Thus, the extraction device 400 can extract the air from the opposite sides of the substrate S supported on the support table 100 via the extraction holes 11.

In the above embodiments, the apparatus 1, 1′ or 1″ is operated in an open atmospheric surrounding; however, it is not limited to this. The whole apparatus may be operated in a closed surrounding as long as the pressure of the surrounding environment ranges from 500 to 760 Torr.

The apparatus for deposition of the selenium thin-film according to the embodiment of the disclosure is as described above. A method for deposition of the selenium thin-film using the above apparatus is described in the following. The method includes the following steps. First, the substrate S is supported on the support table 100 of the apparatus 1″ by a robot arm (not shown) in an atmospheric pressure environment, as shown in FIG. 4a. Subsequently, the solid-state selenium source 230 is dissociated by the plasma generated from the chamber 210 of the plasma head 200 so that selenium molecules move toward the substrate S along the arrow D shown in FIG. 4b. Simultaneously, the plasma head 200 is moved along the arrow M1 shown in FIG. 4a so that the plasma head 200 and the substrate S move relative to each other until the plasma head 200 is located at a position as shown in FIG. 4c. As a result, the selenium thin-film is deposited on the substrate S.

It is understood that the above method is described based on the drawings of the apparatus 1″; however, it is not limited to this. The above method may be performed by using the apparatus 1 or 1′. In addition, although the deposition of the selenium thin-film is completed by moving the plasma head in a single direction once in the above description, it is not limited to this. Based on process requirements, the deposition of the selenium thin-film may be completed by moving the plasma head back and forth once or twice.

When the selenium thin-film is deposited on the substrate S, the substrate S may be simultaneously heated at a temperature range below 500° C. Also, the extraction device 400 may simultaneously extract the air from the opposite sides of the substrate S when the selenium thin-film is deposited on the substrate S.

When the substrate S is a non sodium alkaline glass substrate, sodium fluoride from the sodium fluoride source 240 is introduced into the plasma head 200 via the inlet 222 after the selenium thin-film is being deposited on the substrate S, thus supplying sodium. Like the deposition of the selenium thin-film, the supply of sodium can be completed by moving the plasma head, and detailed description thereof is omitted.

While the disclosure has been described by way of example and in terms of preferred embodiment, it is to be understood that the disclosure is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for deposition of a selenium thin-film, comprising:
providing a plasma head;
supporting a substrate in an atmospheric pressure; and
dissociating a solid-state selenium source by the plasma head to deposit the selenium thin-film on the substrate.

2. The method as claimed in claim 1, wherein the plasma head and the substrate move relative to each other when the selenium thin-film is deposited on the substrate.

3. The method as claimed in claim 2, wherein the relative movement between the plasma head and the substrate is performed by moving the plasma head.

4. The method as claimed in claim 1, further comprising:
heating the substrate when the selenium thin-film is deposited on the substrate.

5. The method as claimed in claim 4, wherein the substrate is heated at a temperature range below 500° C.

6. The method as claimed in claim 1, wherein the substrate is a non sodium alkaline glass substrate, and the method further comprises:
supplying sodium on the substrate after the selenium thin-film is being deposited on the substrate.

7. The method as claimed in claim 6, wherein the sodium is supplied by introducing sodium fluoride into the plasma head.

8. The method as claimed in claim 1, further comprising:
extracting the air from opposite sides of the substrate when the selenium thin-film is deposited on the substrate.

9. An apparatus for deposition of a selenium thin-film, comprising:
a support table supporting a substrate; and
a plasma head, holding a solid-state selenium source, disposed in a manner such that the plasma head and the support table move relative to each other, wherein the solid-state selenium source is dissociated by the plasma head so that the selenium thin-film is deposited on the substrate.

10. The apparatus as claimed in claim 9, wherein the support table comprises:
a platen supporting the substrate; and
a heating device disposed at the platen to heat the substrate when the selenium thin-film is deposited.

11. The apparatus as claimed in claim 9, wherein the plasma head comprises an inlet.

12. The apparatus as claimed in claim 11, further comprising a sodium fluoride source communicating with the inlet, wherein the substrate is a non sodium alkaline glass substrate, and sodium fluoride from the sodium fluoride source is introduced into the plasma head via the inlet.

13. The apparatus as claimed in claim 9, further comprising a transmission mechanism connected to the plasma head to move the plasma head relative to the support table.

14. The apparatus as claimed in claim 9, wherein the plasma head comprises:
a chamber, generating plasma; and
a housing, holding the solid-state selenium source, connected to the chamber in a manner such that the chamber is surrounded by the housing.

15. The apparatus as claimed in claim 14, wherein the chamber comprises a plasma exit, and the solid-state selenium source is located near the plasma exit.

16. The apparatus as claimed in claim 15, wherein the housing comprises a slit-shaped injection exit facing the plasma exit.

17. The apparatus as claimed in claim 9, further comprising an extraction device, disposed around the support table, extracting the air from opposite sides of the substrate supported on the support table.

18. A plasma head comprising:
a chamber, generating plasma;
a housing connected to the chamber in a manner such that the chamber is surrounded by the housing; and
a solid-state selenium source disposed in the housing.

19. The plasma head as claimed in claim 18, wherein the chamber comprises a plasma exit, and the solid-state selenium source is located near the plasma exit.

20. The plasma head as claimed in claim 19, wherein the housing comprises a slit-shaped injection exit facing the plasma exit.

21. The plasma head as claimed in claim 18, wherein the housing comprises an inlet.
